(19) United States
(12) Patent Application Publication
(10) Pub. No.: US 2007/0137566 A1
(43) Pub. Date: Jun. 21, 2007

(54) Modular device for coating surfaces

(75) Inventors: Tibor Cselle, Grenchen (CH); Mojmir Jilek, Sumperk (CZ)

Correspondence Address: VENABLE LLP, P.O. BOX 34385, WASHINGTON, DC, 20043-9998, US

(73) Assignees: PLATIT AG, Grenchen (CH); PIVOT a.s., Sumperk (CZ)

(21) Appl. No.: 10/575,854

(22) PCT Filed: Oct. 15, 2004
(86) PCT No.: PCT/EP04/11669

§ 371 Date: Jun. 21, 2006

(30) Foreign Application Priority Data
Oct. 17, 2003 (EP) 03405753.9

(51) Int. Cl. C23C 16/00; C23C 14/00

(52) U.S. Cl. 118/715; 118/50

(57) ABSTRACT

The invention relates to a vacuum chamber for coating items (10) in which a physical vapor deposition method (PVD) is carried out. The aim of the invention is to create a vacuum chamber of the aforementioned kind which can be provided with modular cathodes. For this purpose, the vacuum chamber is provided with a plurality of receiving devices in which a plurality of cathodes each can be arranged. A first receiving device (30) for receiving one or more cathodes (40, 42, 44, 46) is provided substantially in the center of the vacuum chamber (20) and two additional receiving devices (32, 34) for receiving at least one cathode (48, 50, 52, 54) each are provided on the edges of the vacuum chamber (20) in a door-like manner.

The present invention relates to a modular device for coating surfaces of items (substrates) by the physical vapour deposition (PVD), in a vacuum, of materials by means of an arc or several arcs, including coating with several layers in various ways, hereinafter referred to as “modular, dedicated coating”. Furthermore, the invention relates to a system comprising such a modular device.

From WO-A-02/50865 a device is known which causes coating, on a workpiece, as a result of deposition of typically two approximately cylindrical targets, wherein the material precipitates on the work piece, thus forming a layer. In WO-A-02/50865 it is also proposed in this context that the target be designed by a certain magnetic field arrangement such that directional material volatilisation can take place and in this way particular effects can be achieved.

From EP-A-135577 a method is known to achieve optimum effects of selective coating in this context.

To this effect one or several substantially cylindrical cathodes are arranged in the coating chamber, and by means of magnetic sources, deposition of the material is controlled. In this arrangement the magnetic sources are preferably arranged in the cathodes, and the cathode is rotated in relation to the magnetic field source, or the magnetic field source is rotated in relation to the cathode, in order to in this way achieve even material removal from the target. This material is then deposited on the substrates.

In such a chamber, usually substrates are placed on a rotary table and are successively coated, while the table rotates. From the state of the art it is known to place the cathode, for example, in the centre of the rotary table so as to be able, in this way, to carry out coating of several items in one chamber.

By their citation, the two above-mentioned patent specifications herewith, to the full extent, become part of the present patent specification.

An arrangement according to WO-A-02/50865 can be considered a successful device if approximately bar-shaped items are to be coated. In this case a corresponding coating chamber will be selected. However, it has been found that a coating chamber that is to be suitable for a large variety of items to be coated has to be more versatile.

It is thus first of all the object of the invention to state a variable coating chamber or a variable arrangement of coating means that is also suitable for other items to be coated, so that the coating chamber is more variable than is the case according to the known state of the art.

The invention meets this object by an arrangement according to claim 1. In this arrangement the measures of the invention first of all result in a plurality of coating situations to be able to be treated by the modular arrangement.

The arrangement is used to receive a coating system that also forms part of the invention.

Advantageous embodiments of the invention are stated in the dependent claims.

A corresponding system to solve the problem is claimed in claim 6.

The above-mentioned, as well as the claimed process steps that are to be used according to the invention and that are described in the following embodiments, and the associated elements are not subject to any particular exceptional conditions as far as their size, design, material use and technical concept are concerned, so that the selection criteria known in the respective field of application can be applied without any limitations.

Further details, characteristics and advantages of the object according to the invention are contained in the following description of the associated drawings, in which in an exemplary way a modular device according to the present invention is explained.

The drawings show the following:

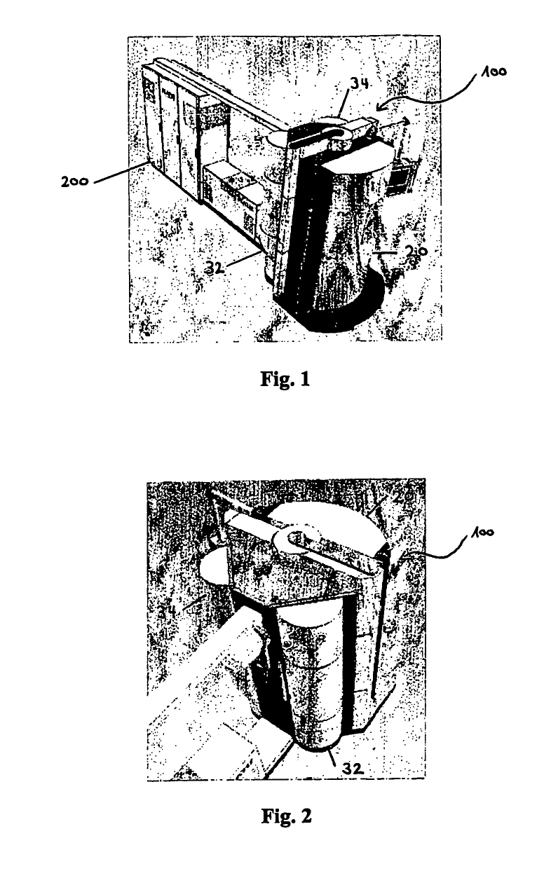

FIG. 1 a perspective view of a coating chamber, in which the arrangement according to the present invention is implemented;

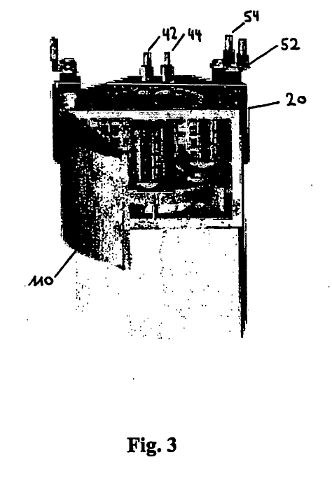

FIG. 2 also a perspective view of the item according to FIG. 1;

FIG. 3 a perspective view of a first configuration of the modular arrangement according to the present invention;

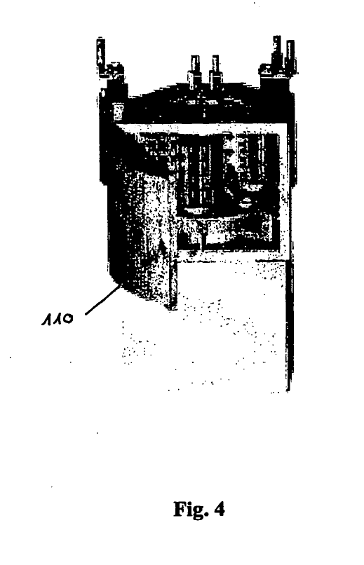

FIG. 4 a perspective view of a second configuration of the modular arrangement according to the present invention;

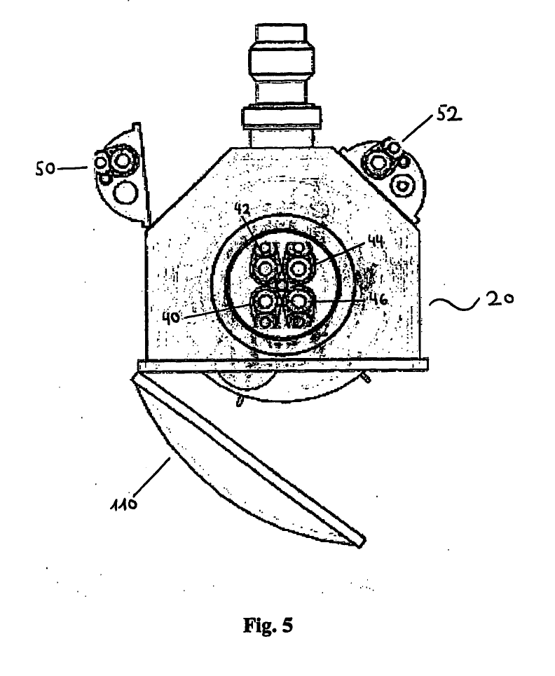

FIG. 5 a top view of the configuration according to FIG. 4;

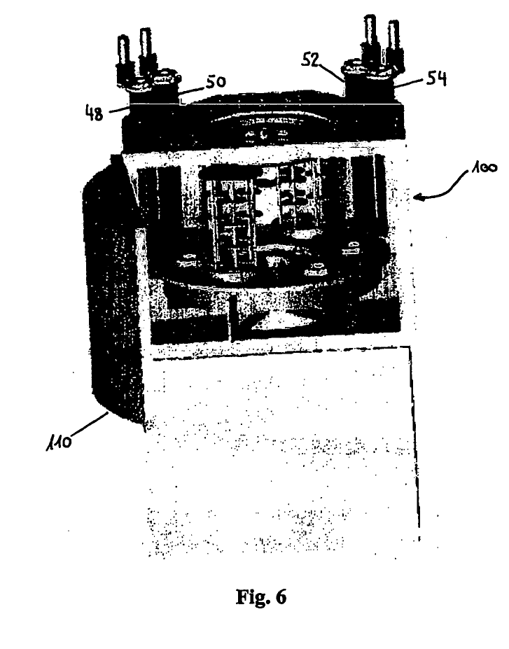

FIG. 6 a perspective view of a third configuration of the modular arrangement according to the present invention;

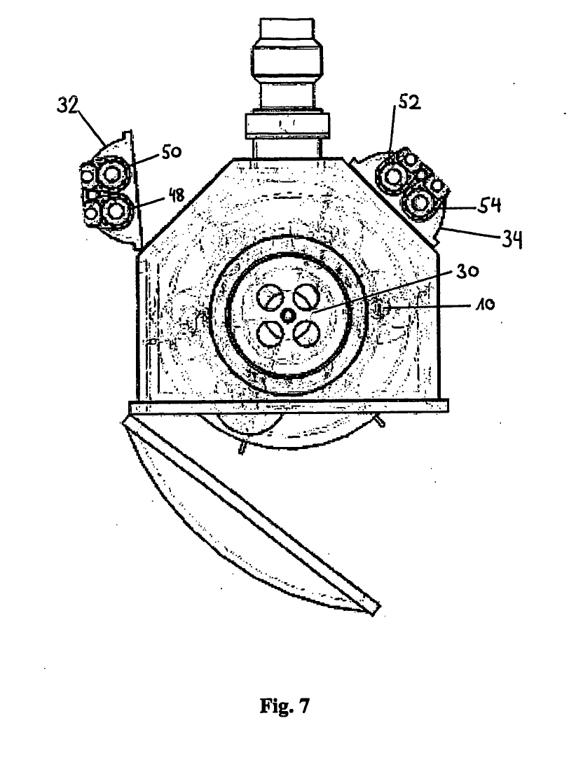

FIG. 7 a top view of the configuration according to FIG. 6;

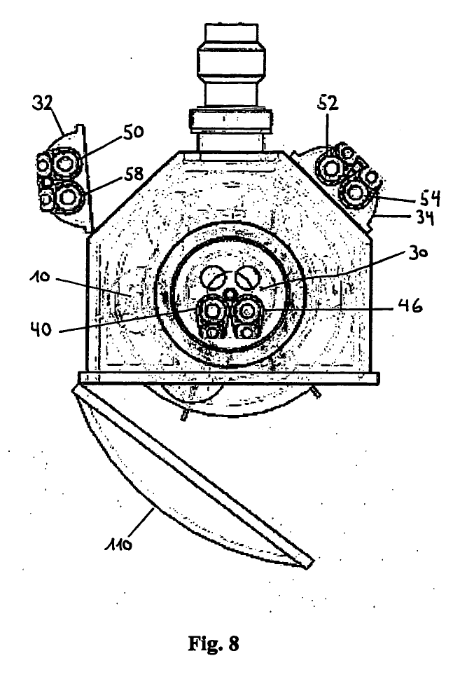

FIG. 8 a top view of a fourth configuration of the modular arrangement according to the present invention;

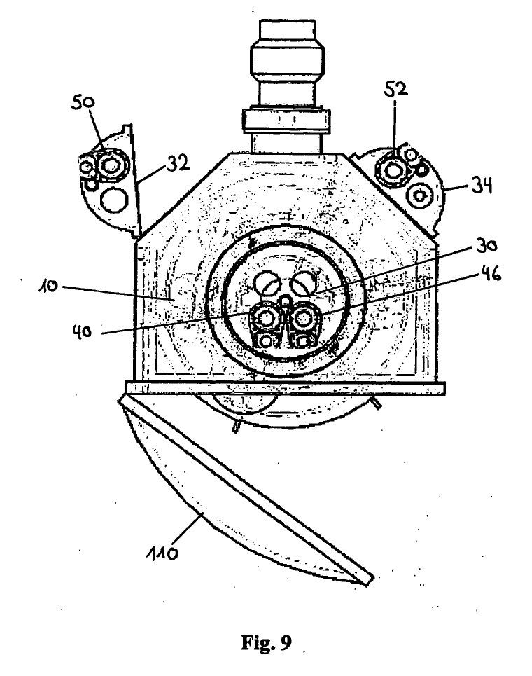

FIG. 9 a top view of a fifth configuration of the modular arrangement according to the present invention;

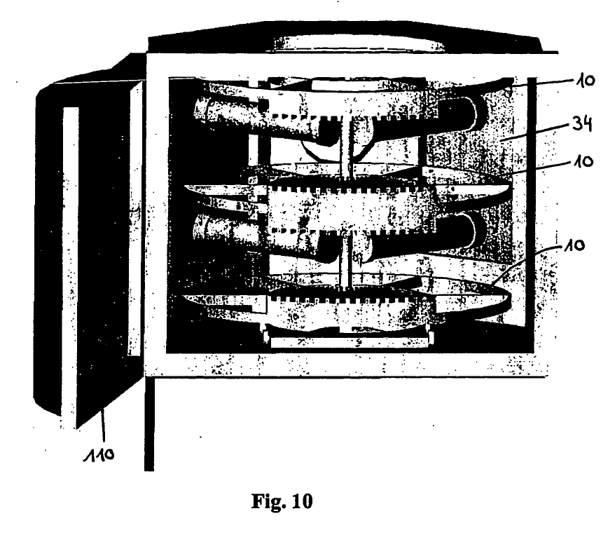

FIG. 10 a perspective view of a configuration with horizontal cathodes (sixth configuration);

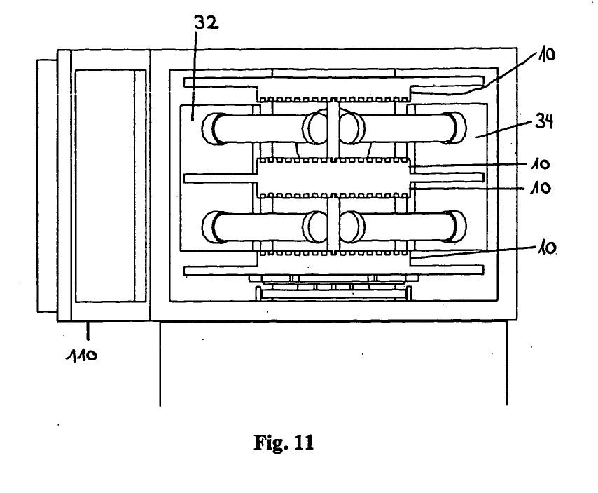

FIG. 11 a lateral view of the configuration with horizontal cathodes according to FIG. 10;

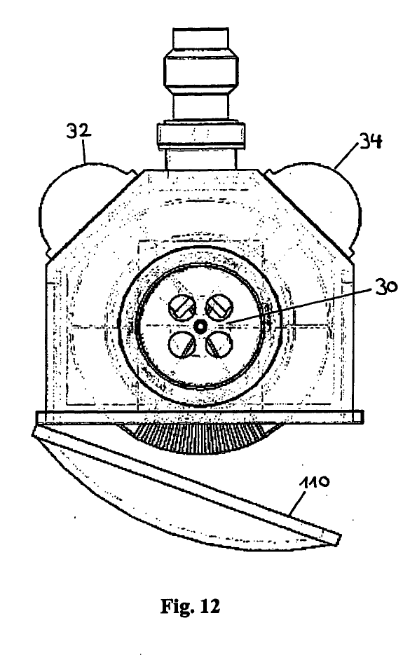

FIG. 12 a top view of the configuration with horizontal cathodes according to FIG. 10;

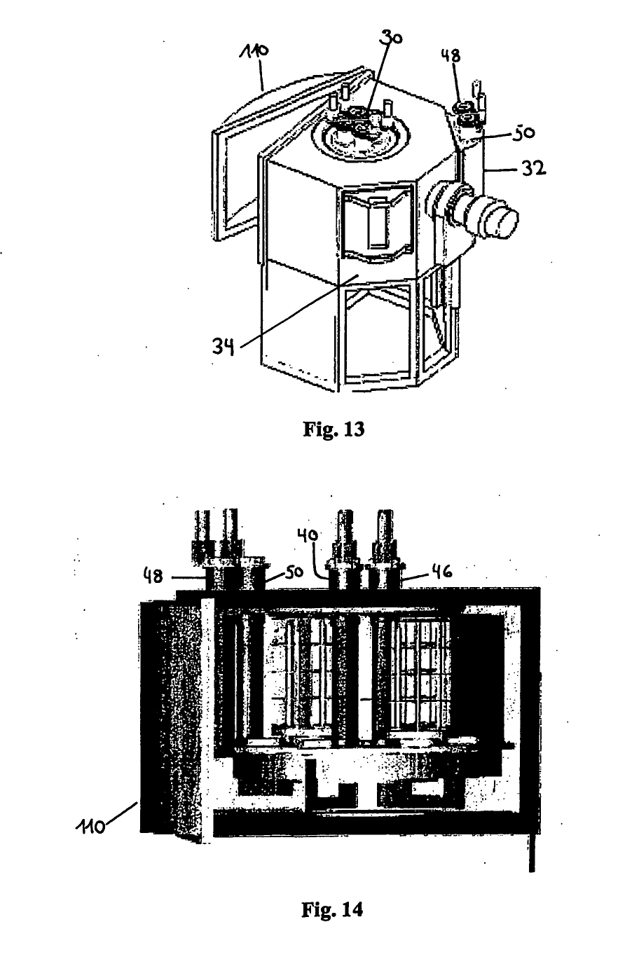

FIG. 13 a perspective view of a configuration according to FIG. 1, except with a planar cathode (seventh configuration);

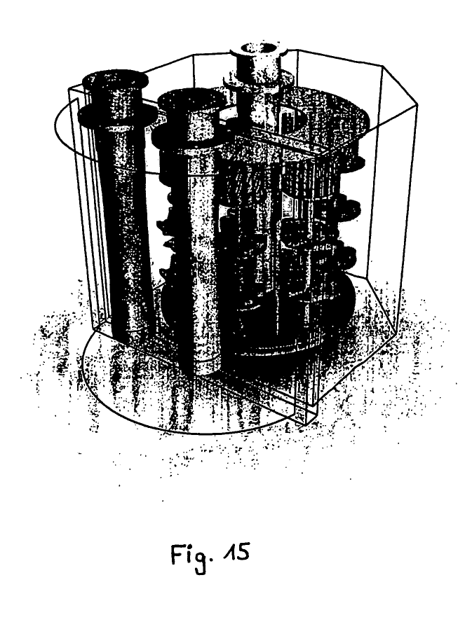

FIG. 14 a lateral view of the configuration according to FIG. 13;

FIG. 15 a cathode arrangement for the system according to the invention.

FIG. 1 shows a coating setup as an overall system 100 with the associated electronics 200.

The core piece of the system is the coating chamber which, as is particularly clearly evident from FIG. 2, comprises two or several devices 32, 34 in a door-like manner on its sides. In these devices cathodes can be received, in addition to the internal receiving devices for cathodes, which receiving devices are already known from the state of the art, mainly in greatly varying configurations, of which some are principally described below.

As the first configuration, FIG. 3 shows the full configuration of the modular arrangement according to the embodiment described herein. In the chamber 100 with an access door 110, at the centre there is an arrangement comprising 4 rotary cathodes 40, 42, 44, 46. Furthermore, on the sides of the described devices 32, 34, in a door-like manner, two further cathodes 48, 50, 52 and 54 each are accommodated. Around the centrally arranged cathodes a substrate holder is arranged in the manner of a rotary table, on which substrate holder a plurality of substrates is accommodated. When coating takes place in this configuration, all cathodes are made from the same material if applicable, but this is not mandatory. In this configuration the best rate of deposition or the best coating rate is then achieved.

For the sake of completeness it should be pointed out that the rotary cathodes are preferably operated in the manner as proposed in the cited state of the art, in other words with a device for the directional forming of arcs.

The second configuration according to FIGS. 4 and 5 at a first glance differs from the above-described first configuration only in that apart from the four cathodes 40, 42, 44 and 46, as discussed, in the internal region each of the two external stations 32 and 34 are equipped only with one cathode 48 and 52 each. In this configuration, at a high rate of deposition in the internal region, the outside cathodes 48 and 52 are used for special tasks, e.g. for ion etching or for depositing alternative layers. Such alternative layers can be diamond coatings or for example lubrication coatings. It should be emphasised that the external cathodes can be operated simultaneously with, or separated in time from, the internal cathodes or in relation to each other, depending on the special coating task.

The other characteristics of the second configuration correspond to those of the first configuration.

In the third configuration according to FIGS. 6 and 7 only the two external stations 32 and 34 are each equipped with two cathodes in order to be able, for example, to coat large parts (forging dies or circular saw blades etc.) from the outside. In this configuration the internal station 30 remains free. The other characteristics of the third configuration correspond to those of the second configuration.

The fourth configuration according to FIG. 8 differs from the above-described first configuration in that apart from the 4 cathodes 48, 50, 52 and 54 in the external region, on the internal station 30 only two cathodes are provided, namely the cathodes 40 and 46, which are arranged so as to be remote from the external stations. In this configuration it is not possible to influence the plasma between the cathodes of the external stations 32 and 34 and that of the internal station 30.

The fifth configuration according to FIG. 9 differs from the above-described first configuration in that only two cathodes 48 and 52 are provided in the external region and only two cathodes are provided on the internal station 30, namely the cathodes 40 and 46, which are arranged so as to be remote from the external stations. This is a further typical configuration of an alternative coating, wherein again the cathodes of the external stations and of the internal station typically comprise different materials.

Surprisingly, it has been shown that the configuration according to FIGS. 10 to 12 can be made and operated particularly well with the arrangement according to the invention. In this configuration the two external stations 32 and 34 comprise two horizontally arranged rotation cathodes each. In this case horizontal effective surfaces are formed as they are for example useful for bandsaws and other flat items. In the present configuration the two cathodes each are used to coat a total of four surfaces, as shown in FIG. 10. This configuration provides a special advantage in that large diameters can be loaded, and homogeneous coating on the effective surface is possible, e.g. the free surface of bandsaws or the face surface of mould and dies without any detrimental differences in coating thickness.

The seventh configuration according to FIGS. 13 and 14 differs from the above-described first configuration in that apart from the four cathodes 40, 42, 44, and 46, as mentioned, in the internal region only one external station 32 comprises two rotary cathodes 48 and 50. The other external station 34 is equipped with one or several conventional planar cathode(s).

FIG. 15 shows a cathode arrangement.

The average person skilled in the art will recognise that the above-described configurations are not exhaustive but merely intended to provide the average person skilled in the art with exemplary explanations within the scope of the following claims.

1-9. (canceled)

10. A modular device for coating surfaces of items with a vacuum chamber, in which a physical vapour deposition (PVD) method can be carried out;
wherein the vacuum chamber comprises at least one anode means as well as a plurality of receiving devices for cathodes; wherein several arcs between the anode means, of which there is at least one, and the cathodes can be ignited;
wherein a first receiving device for receiving at least one cathode is provided substantially in the centre of the vacuum chamber; and at least one second receiving device for receiving at least one cathode on the edge of the vacuum chamber is provided, and the second receiving device is designed as a removable and/or swing-open door of the vacuum chamber;
characterised in that the second receiving device is designed for receiving several cathodes which can be arranged substantially horizontally and substantially one on top of the other such that they protrude into the vacuum chamber.

11. A modular device for coating surfaces of items, with a vacuum chamber in which a physical vapour deposition (PVD) method can be carried out, wherein the vacuum chamber comprises at least one anode means as well as a plurality of receiving devices for cathodes, wherein several arcs can be ignited between the anode means, of which there is at least one, and the cathodes, wherein a first receiving device for receiving at least one cathode is provided substantially in the centre of the vacuum chamber; and
at least one second receiving device for receiving at least one cathode is provided on the edge of the vacuum chamber, and the second receiving device is designed as a removable and/or swing-open door of the vacuum chamber, characterised in that the first receiving device for accommodating cathodes is designed for receiving optionally one to four cathodes, preferably rotating cathodes, that are arranged so as to be substantially vertical and that are approximately cylindrical in shape.

12. The modular device according to claim 10, characterised in that two second receiving devices are designed for receiving at least two cathodes each on the edge of the vacuum chamber as removable and/or swing-open doors of the vacuum chamber.

13. The modular device according to claim 10, characterised in that the first receiving device for receiving cathodes in the centre of the vacuum chamber is designed for receiving optionally one to four cathodes, preferably rotating cathodes, that are arranged so as to be substantially vertical and that are approximately cylindrical in shape.

14. The modular device according to claim 10, wherein the second receiving device each is designed for receiving the cathodes such that the cathodes are approximately cylindrical in shape.

15. The modular device according to claim 10, comprising a substrate arrangement means for receiving one or several items to be coated.

16. The modular device according to claim 10, wherein the vacuum chamber is the anode means.

17. The modular device according to claim 15, wherein the substrate arrangement means is a rotary carousel, and the rotary carousel is designed around the first receiving device.

18. The modular device according to claim 17, characterised in that the rotary carousel is designed such that on the rotary carousel rotary trolleys can be arranged for receiving items to be coated, and/or for receiving satellites for receiving items to be coated.

19. The modular device according to claim 11, characterised in that two second receiving devices are designed for receiving at least two cathodes each on the edge of the vacuum chamber as removable and/or swing-open doors of the vacuum chamber.

20. The modular device according to claim 11, wherein the second receiving device each is designed for receiving the cathodes such that the cathodes are approximately cylindrical in shape.

21. The modular device according to claim 11, comprising a substrate arrangement means for receiving one or several items to be coated.

22. The modular device according to claim 11, wherein the vacuum chamber is the anode means.
